(19) United States
(12) Patent Application Publication
(10) Pub. No.: US 2008/0151480 A1
(43) Pub. Date: Jun. 26, 2008

(54) PORTABLE TERMINAL WITH FLEXIBLE DISPLAY

(75) Inventors: Woo-Chang CHUNG, Seongnam-si (KR); Yang-Un LEE, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD, Suwon-si (KR)

(21) Appl. No.: 11/828,079

(22) Filed: Jul. 25, 2007

(30) Foreign Application Priority Data
Dec. 21, 2006 (KR) 2006-131810

(51) Int. Cl. H05K 7/14

(52) U.S. Cl. 361/681

(57) ABSTRACT

A portable terminal with a flexible display is disclosed. The portable terminal includes a first housing in which a portion of a flexible display is embedded in such a way to be inserted or drawn from the first housing, a second housing which faces or is separated from the first housing and in which the other portion of the flexible display is embedded in such a way to be inserted or drawn from the second housing, and locking units for fixing the first housing and the second housing in order to expose or hide the flexible display.

### PRIORITY

This application claims the benefit under 35 U.S.C. §119(a) of a Korean Patent Application filed in the Korean Intellectual Property Office on Dec. 21, 2006 and assigned Serial No. 2006-131810, the entire disclosure of which is hereby incorporated by reference.

### BACKGROUND OF THE INVENTION

1. Field of the Invention

The present invention relates to a portable terminal with a flexible display.

2. Description of the Related Art

Conventional portable terminals generally use a Liquid Crystal Display (LCD) having a fixed size and a keypad. Although the LCD of a fixed size has been widely used in various fields, its size cannot be increased in a terminal designed for easy portability. To solve the problem, a flexible display capable of achieving both easy portability and size diversity has been developed.

A terminal having the flexible display mounted therein can be easily carried and its size can also be increased, thereby meeting user's demand.

However, a terminal having a flexible display for practical use has not yet been developed. Therefore, there is a need for a portable terminal which can be easily carried and allows a user to enjoy various moving picture contents with a large display screen.

### SUMMARY OF THE INVENTION

An aspect of the present invention is to address at least the above problems and/or disadvantages and to provide at least the advantages described below. Accordingly, an aspect of the present invention is to provide a portable terminal which includes a display having the overall small and broad size to maintain conventional portability.

According to one aspect of the present invention, there is provided a portable terminal. The portable terminal includes a first housing in which a portion of a flexible display is embedded in such a way to be inserted or drawn from the first housing, a second housing which faces or is separated from the first housing and in which the other portion of the flexible display is embedded in such a way to be inserted or drawn from the second housing, and locking units for fixing the first housing and the second housing in order to expose or hide the flexible display.

### BRIEF DESCRIPTION OF THE DRAWINGS

The above and other features and advantages of an exemplary embodiment of the present invention will be more apparent from the following detailed description taken in conjunction with the accompanying drawings, in which:

FIG. 1 illustrates a process in which a terminal according to the present invention is transformed according to a user's purpose;

FIG. 2 illustrates perspective view of a first housing and a second housing according to the present invention;

FIG. 3 illustrates cross-sections of a first housing and a second housing, viewed from top;

FIG. 4 illustrates cross-sections of a first housing and a second housing, viewed from top, when the first housing and the second housing are fixed in another shape;

FIG. 5 illustrates a keypad at a side of a first housing and a second housing when a portion of a flexible display is exposed;

FIG. 6 illustrates a soft key in a flexible display whose portion is exposed; and

FIG. 7 illustrates a process in which a support at a side of a first housing and a second housing is unfolded.

Throughout the drawings, the same drawing reference numerals will be understood to refer to the same elements, features and structures.

### DETAILED DESCRIPTION OF THE EXEMPLARY EMBODIMENT

The matters defined in the description such as a detailed construction and elements are provided to assist in a comprehensive understanding of an exemplary embodiment of the invention. Accordingly, those of ordinary skill in the art will recognize that various changes and modifications of the embodiment described herein can be made without departing from the scope and spirit of the invention. Also, descriptions of well-known functions and constructions are omitted for clarity and conciseness.

The present invention provides a portable terminal that can be easily carried and allows a user to enjoy various moving picture contents with a broad Liquid Crystal Display (LCD) window using a flexible display having a flexible LCD. To implement such a function, the portable terminal according to the present invention has a structure in which the flexible LCD can be drawn or inserted and the size of the flexible display can be adjusted according to user's purpose.

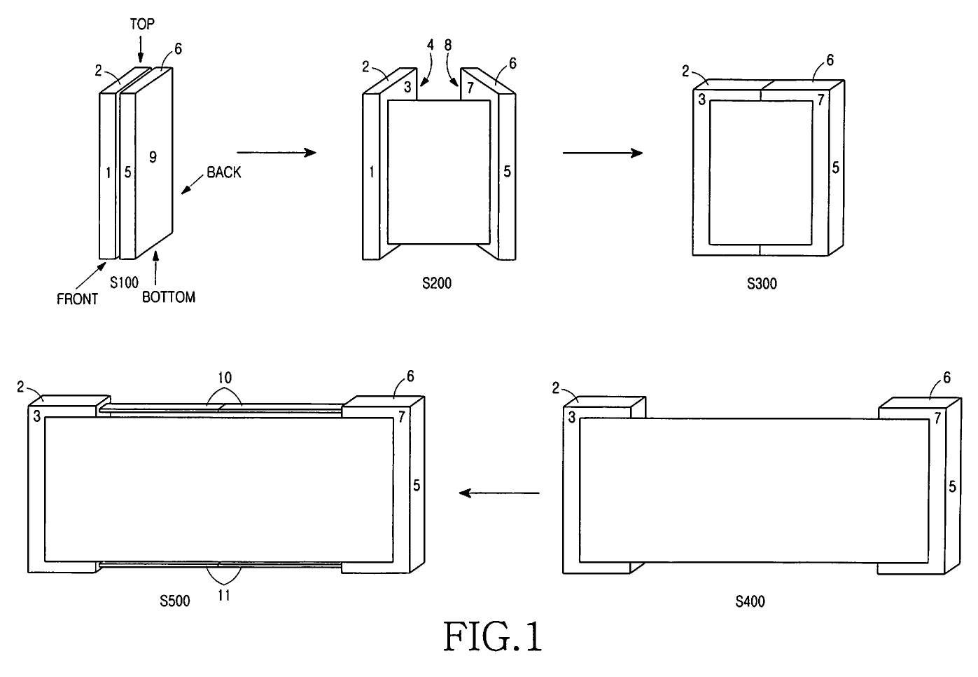

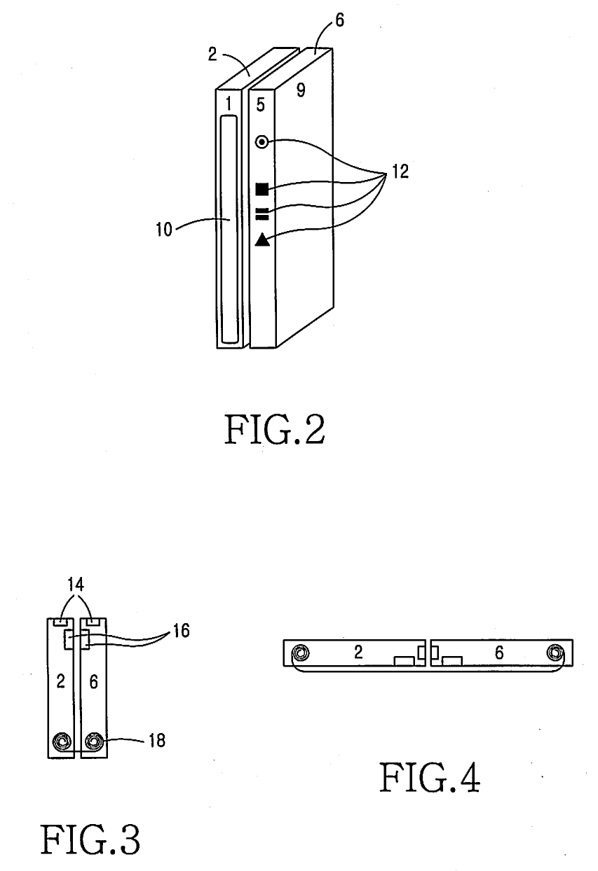

FIG. 1 illustrates a process in which a terminal according to the present invention is transformed according to a user's purpose. In step S100, the terminal includes a first housing and a second housing that face each other. Rotation members capable of rolling up a flexible display are included in the first housing and the second housing. The flexible display may be a flexible LCD made of a thin film. In step S100, a face 3 of the first housing and a face 7 of the second housing face each other. This structure can be implemented by fixing a locking unit of the first housing and a locking unit of the second housing to each other while those locking units face each other. A user can carry the portable terminal in a state as illustrated in step S100. FIG. 2 illustrates an exemplary purpose for which the user can use the portable terminal in the state as illustrated in step S100. In other words, a small LCD 10 is provided in a face 1 of the first housing and a keypad 12 capable of controlling the LCD 10 is provided in a face 5 of the second housing. Thus, the user can enjoy an MP3 function. If the keypad 12 is composed of numeric keys, the user can perform call transmission/reception using the LCD 10 and the keypad 12. Other functions may also be implemented by manufacturers for various purposes.

In step S200, the user separates the first housing and the second housing from each other and thus the embedded flexible display is exposed. At this time, a portion of the flexible display is exposed by rotation of the rotation members of the first housing and the second housing. Step S200 is a process for causing the first housing and the second housing to have a shape illustrated in step S300.

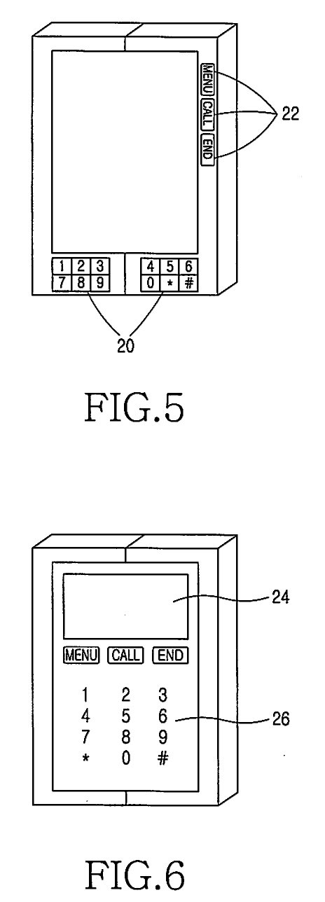

In step S300, a face 4 of the first housing and a face 8 of the second housing face each other. This structure is implemented by fixing the locking unit of the first housing and the locking unit of the second housing to each other while those locking units face each other. The user can quite freely use a cellular phone function of the portable terminal in a state as illustrated in step S300. FIG. 5 illustrates an example in which the user uses the cellular phone function. Referring to FIG. 5, the flexible display exposed can provide an LCD function of a cellular phone and can be controlled by a keypad 20 and other function keys 22.

FIG. 6 illustrates another example in which the user uses the cellular phone function of the portable terminal. Referring to FIG. 6, a soft key 26 is implemented in a portion of the exposed flexible display, thereby allowing keypad input by user's touch. In other words, in step S300 in FIG. 1, the user can use the same functions as those of a general cellular phone. The soft keypad 26 illustrated in FIG. 6 or the keypad 20 illustrated in FIG. 5 can also be implemented with keys of various types capable of representing characters or numbers without being limited to numeric keys. Therefore, a text transmission function using QWERTY key arrangement or a game function using directional keys can also be implemented by manufacturers.

In step S400 in FIG. 1, the flexible display is further exposed by separating the first housing and the second housing from each other, thereby providing a broad LCD. To this end, the user can expose the flexible display rolled up in the first housing and the second housing while separating the first housing and the second housing from each other by a long distance. In this way, the user can view moving pictures with a broad LCD. At this time, the user can adjust the exposed size of the flexible display. The size of displayed content may also be changed to fit into the exposed size of the flexible display.

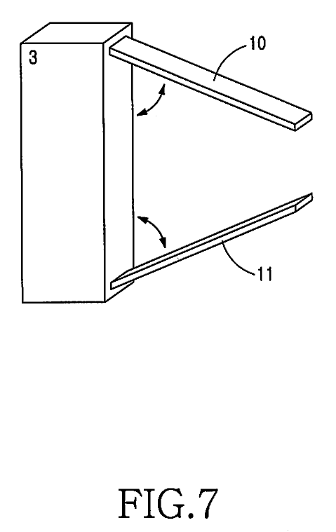

In step S500, after separating the first housing and the second housing by a desired distance, the user pulls out a first support in a face 4 of the first housing and a second support in a face 8 of the second housing to connect them to each other, thereby combining the first housing and the second housing with each other as one body. Each support may be composed of an upper support 10 and a lower support 11 as illustrated in FIG. 7. The first support and the second support can be connected in various ways such as locking using a tool or locking using a magnet. The supports are intended to combine the first housing and the second housing with each other as one body during user's watching of a moving picture, thereby improving stability.

However, step S500 illustrates only an example and the first housing and the second housing may also be combined in various ways. For example, a material that can be attached to a wall may be attached to each of an opposite face to the face 3 of the first housing and an opposite face of the face 7 of the second housing so that the first housing and the second housing may be attached to the wall.

FIG. 3 illustrates cross-sections of the first housing and the second housing in step S100 of FIG. 1, viewed from top, in which locking units 16 for fixing the face 3 of the first housing and the face 7 of the second housing to each other are shown. The locking units 16 may be implemented in various ways such as locking using an instrumental groove, locking using a separate locking button, locking using a magnet, and the like. The flexible display 18 has one end connected to the first housing and the other end connected to the second housing. The flexible display 18 is also rolled up by the rotation members in the first housing and the second housing.

FIG. 4 illustrates cross-sections of the first housing and the second housing in step S300 of FIG. 1, viewed from top, in which locking units 14 for fixing the face 4 of the first housing and the face 8 of the second housing to each other are shown. At this time, a portion of the flexible display is exposed.

As described above, according to the present invention, the user can enjoy moving picture content with a broad LCD window and easily carry the portable terminal. Moreover, the user can use various functions of the portable terminal such as an MP3 player in a first stage, as a cellular phone in the next stage, and as a display device having a broad screen in the final stage according to a user's purpose.

While the invention has been shown and described with reference to an exemplary embodiment thereof, it will be understood by those skilled in the art that various changes in form and details may be made therein without departing from the spirit and scope of the invention.

What is claimed is:

1. A portable terminal comprising:
a first housing in which a portion of a flexible display is embedded in such a way to be inserted or drawn from the first housing;
a second housing which faces or is separated from the first housing and in which an other portion of the flexible display is embedded in such a way to be inserted or drawn from the second housing; and
locking units for fixing the first housing and the second housing in order to expose or hide the flexible display.

2. The portable terminal of claim 1, wherein the flexible display is connected between the first housing and the second housing, and the first housing and the second housing are separated from each other in order to spread the flexible display.

3. The portable terminal of claim 1, wherein the locking units are formed as a pair in one side face of the first housing and one side face of the second housing in such a way that the first housing and the second housing are fixed to each other by at least two configurations.

4. The portable terminal of claim 1, wherein the locking units are fixed by engagement using an instrumental groove.

5. The portable terminal of claim 1, wherein the locking units are fixed by engagement using different poles of a magnet.

6. The portable terminal of claim 1, further comprising a small-size Liquid Crystal Display (LCD) and a keypad capable of controlling the small-size LCD in a first side face of the first housing and a second side face of the second housing.

7. The portable terminal of claim 6, wherein the portable terminal can be used as an MP3 player using the small-size LCD and the keypad in the first side face and the second side face.

8. The portable terminal of claim 1, wherein when the first housing and the second housing are fixed to each other by the locking units in such a way that a segment of the flexible display is exposed, a part of the exposed segment of the flexible display provides a soft keypad of a touch pad type.

9. The portable terminal of claim 1, further comprising a keypad disposed on a keypad surface of the first housing and the second housing when the first housing and the second housing are fixed to each other by the locking units in such a way that a segment of the flexible display is exposed on the keypad surface.

10. The portable terminal of claim 1, wherein each of the first housing and the second housing comprises a rotation member for rolling up and keeping the flexible display therein.

11. The portable terminal of claim 1, further comprising supports capable of connecting the first housing and the second housing with each other as one body when the first housing and the second housing are separated from each other to expose the flexible display.

12. The portable terminal of claim 11, wherein the supports are connected while being spaced apart from the first housing and the second housing by a predetermined angle.

13. The portable terminal of claim 1, wherein the flexible display can change a configuration of an internal screen according to an extent to which the flexible display is exposed from the first housing and the second housing.
